(19) United States
(12) Patent Application Publication
(10) Pub. No.: US 2019/0049854 A1
(43) Pub. Date: Feb. 14, 2019

(54) EXPOSURE DEVICE AND EXPOSURE METHOD THEREOF

(71) Applicants: BOE Technology Group Co., Ltd., Beijing (CN); Beijing BOE Display Technology Co., Ltd., Beijing (CN)

(72) Inventors: Lianjie QU, Beijing (CN); Yonglian QI, Beijing (CN); Yun QIU, Beijing (CN); Hebin ZHAO, Beijing (CN); Bingqiang GUI, Beijing (CN); Jiantao LIU, Beijing (CN)

(21) Appl. No.: 15/920,952

(22) Filed: Mar. 14, 2018

(30) Foreign Application Priority Data
Aug. 9, 2017 (CN) 201710677557.2

(51) Int. Cl. G03F 7/20

(52) U.S. Cl. CPC G03F 7/70308; G03F 7/70358; G03F 7/70316; G03F 7/70008

(57) ABSTRACT

Disclosed are an exposure device and an exposure method thereof. The exposure device includes a stage for placing thereon a substrate to be exposed, a mask arranged above the stage and comprising periodical patterns, an exposure light source arranged above the stage and configured to transmit light at a preset wavelength, and a transparent body configured to move horizontally in a preset direction in an exposure area between the mask and the stage while the exposure light source is exposing in operation. The transparent body is so structured that there is a change in light journey of greater than 2p²/λ at each exposure position in the exposure area while an exposure light source is exposing in operation, where p represents a space between periodical patterns in the mask, and λ represents a preset wavelength of light emitted by the exposure light source.

### CROSS-REFERENCE TO RELATED APPLICATION

This application claims priority of Chinese Patent Application No. 201710677557.2, filed on Aug. 9, 2017, which is hereby incorporated by reference in its entirety.

### FIELD

The present disclosure relates to the field of manufacturing a display, and particularly to an exposure device and an exposure method thereof.

### BACKGROUND

Exposure devices with a higher and higher resolution are required for the existing flat panel display products including Liquid Crystal Displays (LCDs) and Organic Light-Emitting Displays (OLEDs) in that a pattern is fabricated from the original resolution of approximately 5 μm to the existing resolution of approximately 2 μm, and it is difficult for the existing popular large exposure devices for operate beyond the extreme resolution of 1 μm.

In view of this, an exposure device for fabricating a pattern beyond the resolution of 1 μm based upon the Talbot effect has emerged. The Talbot effect refers to such an important optical phenomenon that simply an object can be imaged through a periodical medium under some condition, and typically the image is also periodical. When periodical gratings are illuminated with a monochromatic planar wave, an image of the periodical gratings can be observed at some specific distance behind the gratings, and this phenomenon is referred to as the Talbot effect, and can be applicable to the fields of optical measurement, a periodical array of gratings, optical computing, etc.

### SUMMARY

An embodiment of the disclosure provides an exposure device including: a stage for placing thereon a substrate to be exposed, a mask arranged above the stage, and including periodical patterns, an exposure light source arranged above the stage, and configured to transmit light at a preset wavelength, and a transparent body configured to move horizontally in a preset direction in an exposure area between the mask and the stage while the exposure light source is exposing in operation, wherein the transparent body is so structured that there is a change in light journey, the change in light journey is greater than 2p²/λ at each exposure position in the exposure area while the exposure light source is exposing in operation, wherein p represents the spacing between the periodical patterns in the mask, and λ represents the preset wavelength.

In an optional implementation, in the exposure device above according to the embodiment of the disclosure, the transparent body is a height-gradually-changing body with a height changing gradually in a horizontal movement direction; and there is a uniform refractive index of the height-gradually-changing body.

In an optional implementation, in the exposure device above according to the embodiment of the disclosure, there is a uniform height of respective cross sections of the height-gradually-changing body in a vertical direction perpendicular to the horizontal movement direction.

In an optional implementation, in the exposure device above according to the embodiment of the disclosure, the height-gradually-changing is divided into a first height-gradually-changing portion and a second height-gradually-changing portion, both of which are arranged in the horizontal movement direction; a length of the first height-gradually-changing portion is greater than the length a of the exposure area in the horizontal movement direction, and a difference in height of the first height-gradually-changing portion is greater than 2p²/(λ(n−1)); and a length of the second height-gradually-changing portion is greater than the length of the exposure area A in the horizontal movement direction, and the difference in height of the second height-gradually-changing portion is greater than 2p²/(λ(n−1)); wherein n represents the refractive index of the height-gradually-changing body.

In an optional implementation, in the exposure device above according to the embodiment of the disclosure, there is a maximum height at a position where the first height-gradually-changing portion and the second height-gradually-changing portion are connected.

In an optional implementation, in the exposure device above according to the embodiment of the disclosure, there is a symmetry axis at the position where the first height-gradually-changing portion and the second height-gradually-changing portion are connected, and the height-gradually-changing body is structured symmetric with respect to the symmetry axis.

In an optional implementation, in the exposure device above according to the embodiment of the disclosure, the transparent body is a transparent body with a uniform height and a refractive index changing gradually in the horizontal movement direction.

In an optional implementation, in the exposure device above according to the embodiment of the disclosure, there is a uniform refractive index of respective cross sections of the transparent body in the vertical direction perpendicular to the horizontal movement direction.

In an optional implementation, in the exposure device above according to the embodiment of the disclosure, the transparent body is divided into a first transparent portion and a second transparent portion, both of which are arranged in the horizontal movement direction; a length of the first transparent portion is greater than the length of the exposure area in the horizontal movement direction, and a difference in refractive index of the first transparent portion is greater than 2p²/(λ*H); and a length of the second transparent portion is greater than the length of the exposure area in the horizontal movement direction, and a difference in refractive index of the second transparent portion is greater than 2p²/(λ*H); wherein H represents the height of the transparent body.

In an optional implementation, in the exposure device above according to the embodiment of the disclosure, there is a maximum refractive index at a position where the first transparent portion and the second transparent portion are connected.

In an optional implementation, in the exposure device above according to the embodiment of the disclosure, there may be a symmetry axis at the position where the first transparent portion and the second transparent portion are connected, and the transparent body is structured symmetric with respect to the symmetry axis.

In another aspect, an embodiment of the disclosure further provides an exposure method of the exposure device above, the method includes: arranging the transparent body, covering the exposure area, between the mask and the stage for placing thereon a substrate to be exposed, before the exposure light source exposes in operation; and moving the transparent body horizontally in the preset direction while the exposure light source is exposing in operation, so that there is a change in light journey, the change in light journey is greater than 2p²/λ at each exposure position in the exposure area, wherein p represents a space between the periodical patterns in the mask, and λ represents a preset wavelength of light emitted by the exposure light source.

In an optional implementation, in the exposure method above according to the embodiment of the disclosure, moving the transparent body horizontally in the preset direction includes: moving the transparent body horizontally in the preset direction at a constant velocity.

In an optional implementation, in the exposure method above according to the embodiment of the disclosure, moving the transparent body horizontally in the preset direction at a constant velocity comprises: moving the transparent body having a uniform refractive index horizontally at a constant velocity from an initial position of the transparent body to a stop position of the transparent body; wherein the first height-gradually-changing portion of the transparent body in the horizontal movement direction covers the exposure area at the initial position of the transparent body, and the second height-gradually-changing portion of the transparent body in the horizontal movement direction covers the exposure area at the stop position of the transparent body; or the second height-gradually-changing portion of the transparent body in the horizontal movement direction covers the exposure area at the initial position of the transparent body, and the first height-gradually-changing portion of the transparent body in the horizontal movement direction covers the exposure area at the stop position of the transparent body.

In an optional implementation, in the exposure method above according to the embodiment of the disclosure, moving the transparent body horizontally in the preset direction at a constant velocity comprises: moving the transparent body having a gradually changing refractive index horizontally at a constant velocity from an initial position of the transparent body to a stop position of the transparent body; wherein the first transparent portion of the transparent body in the horizontal movement direction covers the exposure area at the initial position of the transparent body, and the second transparent portion of the transparent body in the horizontal movement direction covers the exposure area at the stop position of the transparent body; or the second transparent portion of the transparent body in the horizontal movement direction covers the exposure area at the initial position of the transparent body, and the first transparent portion of the transparent body in the horizontal movement direction covers the exposure area at the stop position of the transparent body.

### BRIEF DESCRIPTION OF THE DRAWINGS

FIG. 1A and FIG. 1B are schematic structural diagrams of the exposure device in the related art.

FIG. 2A and FIG. 2B are schematic structural diagrams respectively of an exposure device according to an embodiment of the disclosure.

FIG. 3A and FIG. 3B are other schematic structural diagrams respectively of the exposure device according to the embodiment of the disclosure.

FIG. 4A and FIG. 4B are other schematic structural diagrams respectively of the exposure device according to the embodiment of the disclosure.

FIG. 5A and FIG. 5B are other schematic structural diagrams respectively of the exposure device according to the embodiment of the disclosure.

FIG. 6 is another schematic structural diagram of an exposure device according to an embodiment of the disclosure.

### DETAILED DESCRIPTION OF THE EMBODIMENTS

Optional implementations of the exposure device and the exposure method thereof according to the embodiments of the disclosure will be described below in details with reference to the drawings.

The shapes and sizes of respective layers in the drawings are not intended to reflect any real proportion, but only intended to illustrate the disclosure.

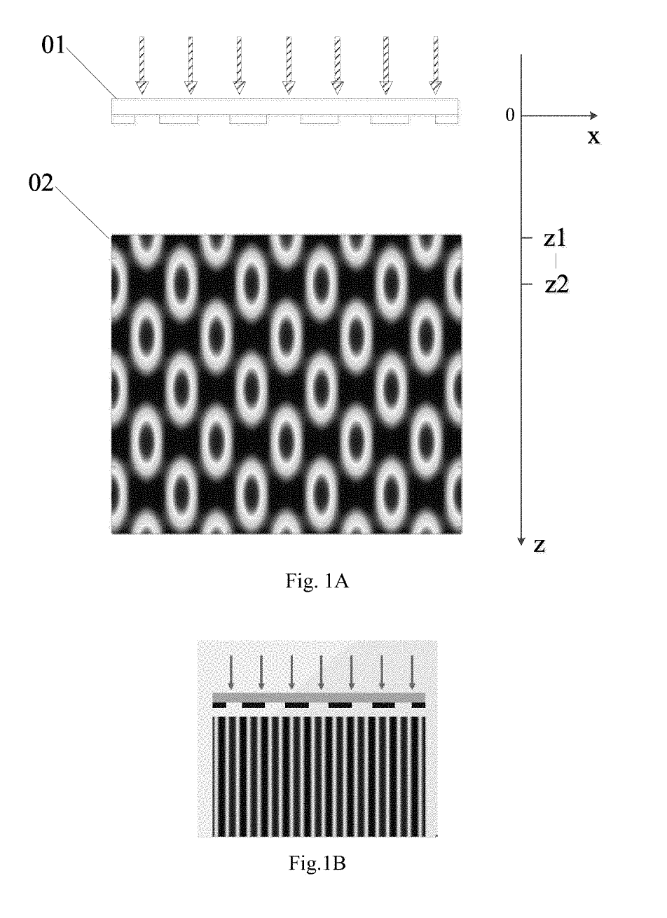

An existing photolithographic device to which the Talbot effect is applied is an exposure device as illustrated in FIG. 1A, and there is such a mask 01 at the zero position in the direction of the z axis that is imaged correspondingly onto the z axis, for example, where the resolution of imaging onto the z axis is twice a pattern resolution of the normal mask 01. However the mask is imaged as respective focuses, so an exposed substrate must move upward and downward along the z axis, thus resulting in the image as illustrated in FIG. 1B. As can be apparent, in order to obtain the exposure image, the exposed substrate must move along the z axis over a distance of at least 2p²/λ, where p represents the spacing between periodical patterns in the mask 01; and λ represents an exposure wavelength. Stated otherwise, the exposed substrate shall move between z1 and z2 along the z axis, and in order for a better exposure effect, it shall move for a number of shortest movement periodicities or upward and downward repeatedly along the z axis, that is, move repeatedly between z1 and z2, thus resulting in the poor precision of aligning the moving exposed substrate, which may affect an exposure effect.

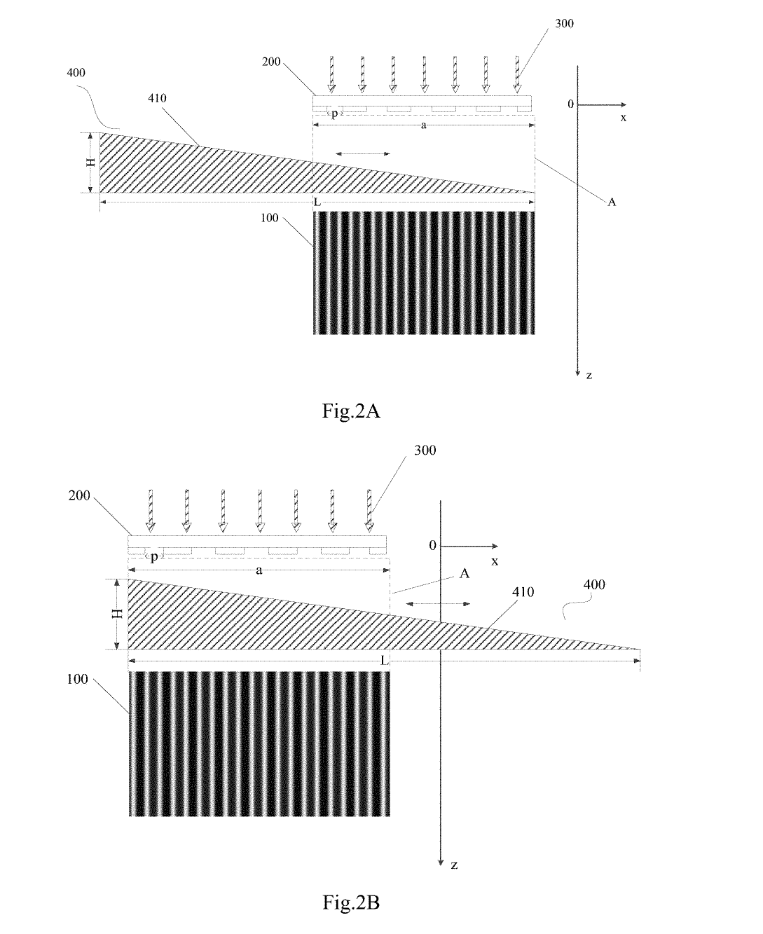

As illustrated in FIG. 2A to FIG. 6, a Talbot effect based exposure device according to an embodiment of the disclosure includes a stage 100 for placing thereon a substrate to be exposed, a mask 200 arranged above the stage 100 and including periodical patterns, an exposure light source 300 arranged above the stage 100 and configured to transmit light at a preset wavelength, and a transparent body 400 configured to move horizontally in a preset direction in an exposure area A between the mask 200 and the stage 100 while the exposure light source 300 is exposing in operation.

The transparent body 400 is so structured that there is a change in light journey of greater than 2p²/λ at each exposure position in the exposure area A while the exposure light source 300 is exposing in operation, where p represents the spacing between the periodical patterns in the mask 200, and λ represents the preset wavelength.

Optionally in the exposure device above based upon the Talbot effect according to the embodiment of the disclosure, the transparent body 400 moves horizontally in the exposure area A between the mask 200, and the stage 100 for placing thereon a substrate to be exposed, instead of the exposed substrate moving upward and downward for exposure in the related art. Optionally the transparent body 400 moves horizontally to thereby change longitudinal light journeys at the respective exposure positions in the exposure area A, so that the longitudinal light journeys are changed due to the easily manipulated horizontal movement of the transparent body instead of changing the optical distance due to the insignificant movement of the substrate to be exposed, to thereby avoid the poor precision of aligning the moving exposed substrate under a satisfactory exposure condition as needed.

Optionally the exposure device above according to the embodiment of the disclosure can enable a highly uniform pattern to be fabricated with a resolution of less than 1 μm, and even a high resolution of 0.05 μm to 0.5 μm.

It shall be noted that in the exposure device above according to the embodiment of the disclosure, the exposure area A between the mask 200 and the stage 100 refers to such an area of the substrate to be exposed, on the stage 100, that is illuminated by the exposure light source, and generally the area of the exposure area A is slightly larger than the area of the substrate to be exposed, so that the entire layer to be exposed, e.g., photoresist, on the substrate to be exposed is located in the exposure area A.

In an optional implementation, in the exposure device above according to the embodiment of the disclosure, the transparent body 400 shall keep on moving horizontally while the exposure light source 300 is exposing in operation, that is, emitting the light at the preset wavelength to illuminate the substrate to be exposed, so that the light journeys at the respective exposure positions in the exposure area A are changing constantly instead of such a light journey at some exposure position that is unchanged for a long period of time, which would otherwise affect a resulting exposure effect. The transparent body 400 will keep on moving rightward horizontally throughout the following description, for example, but in an optional implementation, the transparent body 400 can move leftward and rightward repeatedly (i.e. move repeatedly along x axis), or can move unidirectionally, and the movement direction and distance thereof shall be determined according to the length of the exposure time, and the size of the exposure area, although the embodiment of the disclosure will not be limited thereto.

Furthermore optionally the light journeys at the respective exposure positions in the exposure area shall change uniformly for a better exposure effect, so the transparent body 400 shall generally cover the entire exposure area A in the exposure process, and the transparent body 400 shall move at a constant velocity in the exposure process, so that the light journeys at the respective exposure positions in the exposure area A change uniformly.

Hereupon in the exposure device above according to the embodiment of the disclosure, the transparent body 400 can be embodied in a number of structures to perform the function above, and as can be apparent from the function to be performed by the transparent body 400 to being move so that there is a change in light journey of greater than 2p²/λ at each exposure position, the transparent body 400 shall provide a change in light journey of (n−1)H, where n represents the refractive index of the transparent body 400, and H represents the height of the transparent body, so a journey of light rays transmitted through the horizontally moving transparent body 400 can be changed by changing the refractive indexes or the heights of the transparent body 400 at the respective positions.

Optionally in the exposure device above according to the embodiment of the disclosure, as illustrated in FIG. 2A and FIG. 2B, the transparent body 400 can be a height-gradually-changing body 410 with a height H changing gradually in the horizontal movement direction; and there is a uniform refractive index of the height-gradually-changing body 410, that is, a journey of light rays transmitted through the horizontally moving transparent body 400 can be changed by changing the height of the transparent body 400 given the refractive index n thereof. Furthermore in order to enable a change in light journey of greater than 2p²/λ at each exposure position due to the difference in height of the height-gradually-changing body 410 in the vertical direction, the difference in height of the height-gradually-changing body 410 shall be greater than 2*2p²/(λ*(n−1)).

In an optional implementation, in the exposure device above according to the embodiment of the disclosure, there is a uniform height of respective cross sections of the height-gradually-changing body 410 in the vertical direction perpendicular to the horizontal movement direction, that is, the height-gradually-changing body 410 can be a wedged height-gradually-changing body 410, that is, there is a uniform thickness of the height-gradually-changing body 410 in the direction perpendicular to the paper.

Optionally FIG. 2A illustrates an initial position of the height-gradually-changing body 410 in an exposure process, and correspondingly FIG. 2B illustrates a stop position of the height-gradually-changing body 410 at the end of the exposure process; and the position illustrated in FIG. 2B can also be an initial position of the height-gradually-changing body 410 in a next exposure process, and correspondingly the position illustrated in FIG. 2A can also be a stop position of the height-gradually-changing body 410 at the end of the next exposure process.

Optionally in the exposure device illustrated in FIG. 2A and FIG. 2B according to the embodiment of the disclosure, the height-gradually-changing body 410 is a wedged height-gradually-changing body 410 with the height thereof decreasing gradually from the left to the right, and in order to enable the height-gradually-changing body 410 to cover the entire exposure area A in the exposure process, the length L of the height-gradually-changing body 410 is greater than twice the length a of the exposure area A in the horizontal movement direction.

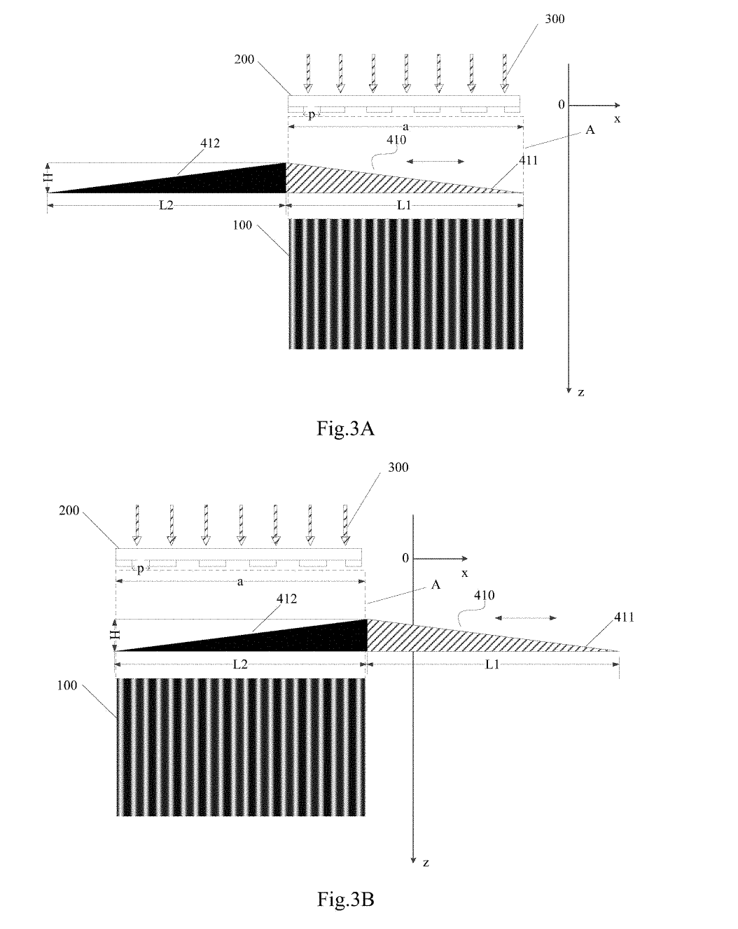

In order to enable a uniform average light journey at the respective exposure positions so as to facilitate the uniformity of the resulting exposure pattern, in an optional implementation, in the exposure device above according to the embodiment of the disclosure, as illustrated in FIG. 3A and FIG. 3B, the height-gradually-changing body 410 can be further divided into a first height-gradually-changing portion 411 and a second height-gradually-changing portion 412, both of which are arranged in the horizontal movement direction.

The length L1 of the first height-gradually-changing portion 411 is greater than the length a of the exposure area A in the horizontal movement direction, and the difference in height of the first height-gradually-changing portion 411 is greater than 2p²/λ*(n−1)).

The length L2 of the second height-gradually-changing portion 412 is greater than the length of the exposure area A in the horizontal movement direction, and the difference in height of the second height-gradually-changing portion 412 is greater than 2p²/λ*(n−1)).

Where n represents the refractive index of the height-gradually-changing body 410, and L1 may or may not be equal to L2.

Optionally FIG. 3A illustrates an initial position of the height-gradually-changing body 410 in the exposure process, where the first height-gradually-changing portion 411 covers the entire exposure area, and correspondingly FIG. 3B illustrates a stop position of the height-gradually-changing body 410 at the end of the exposure process, where the second height-gradually-changing portion 412 covers the entire exposure area; or FIG. 3B illustrates an initial position of the height-gradually-changing body 410 in the exposure process, where the second height-gradually-changing portion 412 covers the entire exposure area, and correspondingly FIG. 3A illustrates a stop position of the height-gradually-changing body 410 at the end of the exposure process, where the first height-gradually-changing portion 411 covers the entire exposure area.

In this way, there can be the same average light journey at the respective exposure positions in the exposure area A while there is a uniform change in light journey which is greater than 2p²/λ at each exposure position, thus enabling the resulting exposure pattern to be imaged uniformly.

In an optional implementation, in the exposure device above according to the embodiment of the disclosure, as illustrated in FIG. 3A and FIG. 3B, there is the maximum height at the position where the first height-gradually-changing portion 411 and the second height-gradually-changing portion 412 are connected, that is, the height of the height-gradually-changing body 410 is the maximum at the middle thereof, and the minimum at two ends thereof; or there is the minimum height at the position where the first height-gradually-changing portion 411 and the second height-gradually-changing portion 412 are connected, that is, the height of the height-gradually-changing body 410 is the minimum at the middle thereof, and the maximum at two ends thereof.

In an optional implementation, in the exposure device above according to the embodiment of the disclosure, in order to further enable the same average light journey at the respective exposure positions so as to enable the resulting exposure pattern to be image uniformly, as illustrated in FIG. 3A and FIG. 3B, there may be a symmetry axis at the position where the first height-gradually-changing portion 411 and the second height-gradually-changing portion 412 are connected, and the height-gradually-changing body 410 may be structured symmetric with respect to the symmetry axis, that is, the left and right halves of the height-gradually-changing body 410 are symmetric to each other.

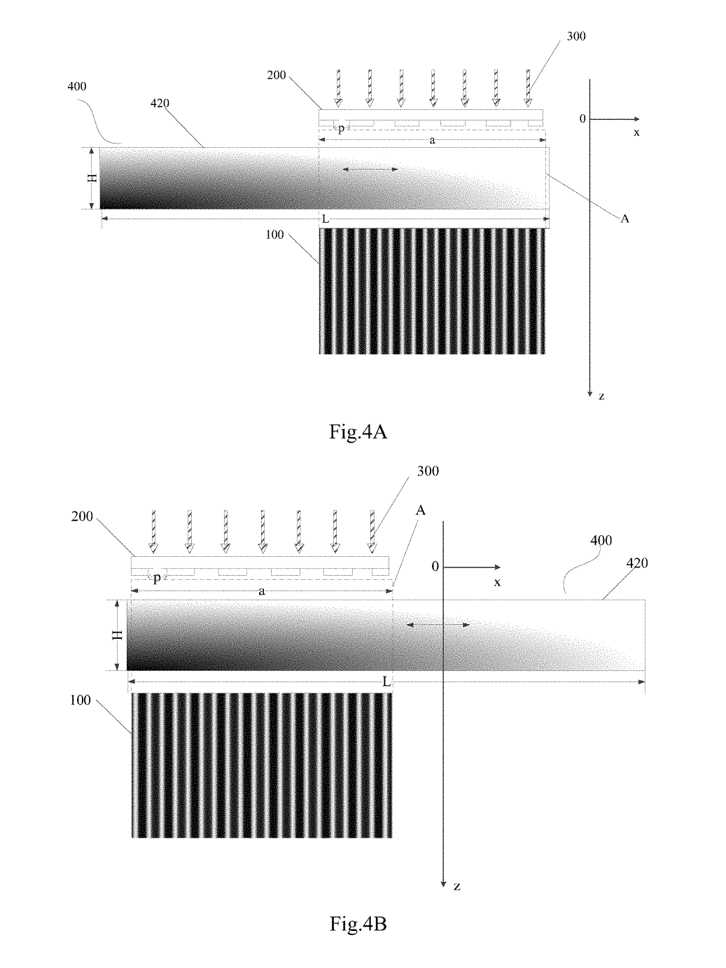

The structure of the transparent body 400 may be the height-gradually-changing body 410 with the height H thereof changing gradually in the horizontal movement direction as described above, but optionally in the exposure device above according to the embodiment of the disclosure, as illustrated in FIG. 4A and FIG. 4B, the transparent body 400 can alternatively be a transparent body 420 with a uniform height, and a refractive index changing gradually in the horizontal movement direction, that is, a journey of light rays transmitted through the horizontally moving transparent body 400 can be changed by changing the refractive index of the transparent body 400 given the height H thereof. Furthermore in order to enable a change in light journey which is greater than 2p²/λ at each exposure position due to the difference in refractive index of the transparent body 420 in the vertical direction, the difference in refractive index of the transparent body 420 shall be greater than 2*2p²/(λ*H)−1.

In an optional implementation, in the exposure device above according to the embodiment of the disclosure, there is a uniform refractive index of respective cross sections of the transparent body 420 in the vertical direction perpendicular to the horizontal movement direction, that is, the transparent body 420 can be a wedged transparent body 420, that is, there is a uniform thickness of the transparent body 420 in the direction perpendicular to the paper.

Optionally FIG. 4A illustrates an initial position of the transparent body 420 in an exposure process, and correspondingly FIG. 4B illustrates a stop position of the transparent body 420 at the end of the exposure process; and the position illustrated in FIG. 4B can also be an initial position of the transparent body 420 in a next exposure process, and correspondingly the position illustrated in FIG. 4A can also be a stop position of the transparent body 420 at the end of the next exposure process.

Optionally in the exposure device illustrated in FIG. 4A and FIG. 4B according to the embodiment of the disclosure, the transparent body 420 is a wedged transparent body 420 with the refractive index thereof decreasing gradually from the left to the right, and in order to enable the transparent body 420 to cover the entire exposure area A in the exposure process, the length L of the transparent body 420 is greater than twice the length a of the exposure area A in the horizontal movement direction.

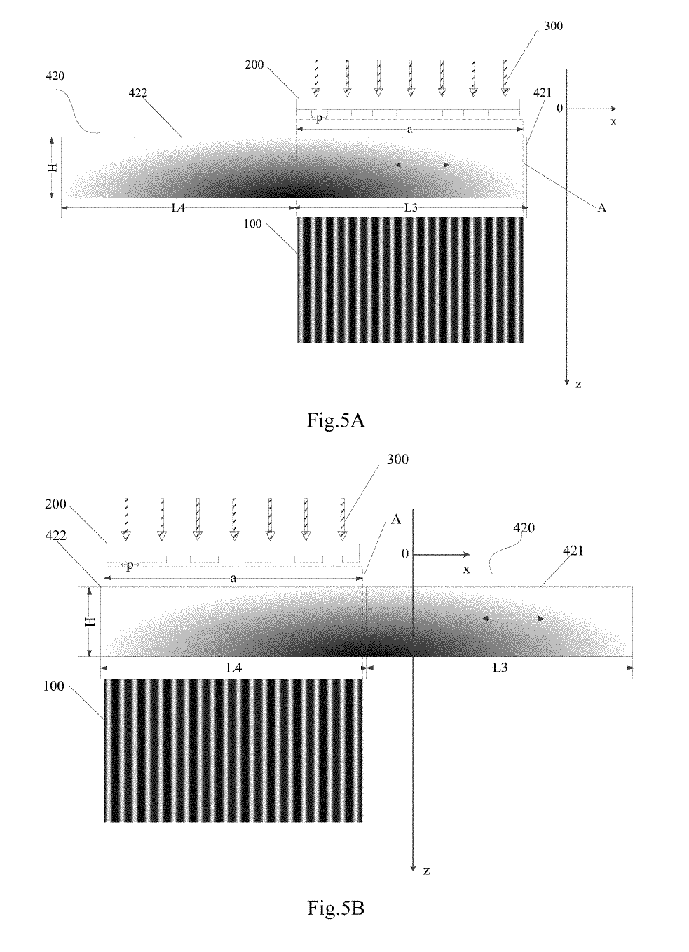

In order to enable a uniform average light journey at the respective exposure positions so as to facilitate the uniformity of the resulting exposure pattern, in an optional implementation, in the exposure device above according to the embodiment of the disclosure, as illustrated in FIG. 5A and FIG. 5B, the transparent body 420 can be further divided into a first transparent portion 421 and a second transparent portion 422, both of which are arranged in the horizontal movement direction.

The length L3 of the first transparent portion 421 is greater than the length of the exposure area A in the horizontal movement direction, and the difference in refractive index of the first transparent portion 421 is greater than 2p²/(λ*H).

The length L4 of the second transparent portion 422 is greater than the length of the exposure area A in the horizontal movement direction, and the difference in refractive index of the second transparent portion 422 is greater than 2p²/(λ*H).

Where H represents the height of the transparent body 420, and L3 may or may not be equal to L4.

Optionally FIG. 5A illustrates an initial position of the transparent body 420 in the exposure process, where the first transparent portion 421 covers the entire exposure area, and correspondingly FIG. 5B illustrates a stop position of the transparent body 420 at the end of the exposure process, where the second transparent portion 422 covers the entire exposure area; or FIG. 5B illustrates an initial position of the transparent body 420 in the exposure process, where the second transparent portion 422covers the entire exposure area, and correspondingly FIG. 5A illustrates a stop position of the transparent body 420 at the end of the exposure process, where the first transparent portion 421 covers the entire exposure area.

In this way, there can be the same average light journey at the respective exposure positions in the exposure area A while there is a uniform change in light journey which is greater than 2p²/λ at each exposure position, thus enabling the resulting exposure pattern to be imaged uniformly.

In an optional implementation, in the exposure device above according to the embodiment of the disclosure, as illustrated in FIG. 5A and FIG. 5B, there is the maximum refractive index at the position where the first transparent portion 421 and the second transparent portion 422 are connected, that is, the refractive index of the transparent body 420 is the maximum at the middle thereof, and the minimum at two ends thereof; or there is the minimum height at the position where the first transparent portion 421 and the second transparent portion 422 are connected, that is, the refractive index of the transparent body 420 is the minimum at the middle thereof, and the maximum at two ends thereof.

In an optional implementation, in the exposure device above according to the embodiment of the disclosure, in order to further enable the same average light journey at the respective exposure positions so as to enable the resulting exposure pattern to be image uniformly, as illustrated in FIG. 5A and FIG. 5B, there may be a symmetry axis at the position where the first transparent portion 421 and the second transparent portion 422 are connected, and the transparent body 420 may be structured symmetric with respect to the symmetry axis, that is, the left and right halves of the transparent body 420 are symmetric to each other.

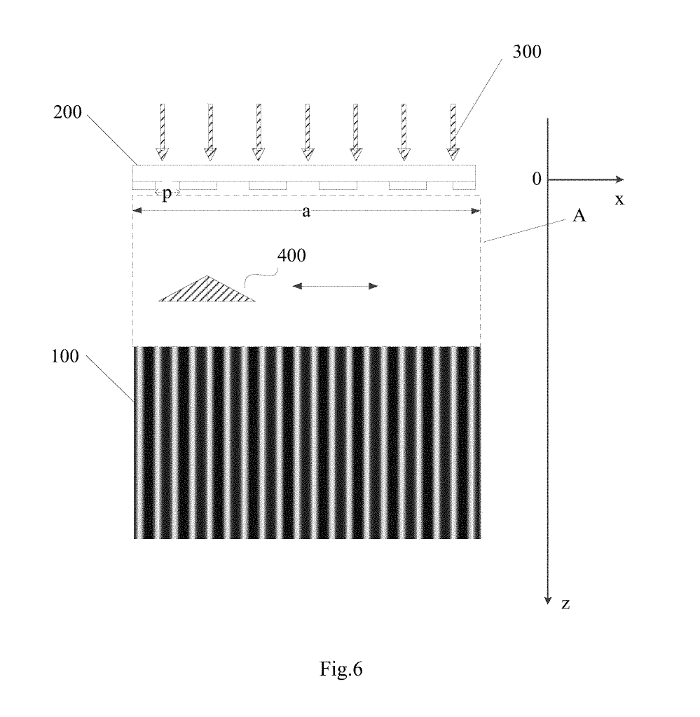

The structure of the transparent body 400 may be the transparent body 420 with the refractive index n thereof changing gradually in the horizontal movement direction as described above, but optionally in the exposure device above according to the embodiment of the disclosure, the transparent body 400 can alternatively be a structure with a height and a refractive index, both of which are changing, as long as there is such a structure thereof that there is a change in light journey of greater than 2p²/λ at each exposure position in the exposure area A. Furthermore the area of the transparent body 400 can alternatively be smaller than the exposure area A as illustrated in FIG. 6, for example, and at this time, the transparent body 400 shall move at a high velocity in the exposure process so that a light journey at each exposure position in the exposure area A will not be unchanged for a long period of time.

Based upon the same inventive idea, an embodiment of the disclosure further provides an exposure method of the exposure device above, and since the method addresses the problem under a similar principle to the exposure device above, reference can be made to the implementation of the exposure device for an implementation of the method, and a repeated description thereof will be omitted here.

Optionally an embodiment of the disclosure further provides an exposure method of the exposure device above, where the method includes the following steps.

Arranging the transparent body, covering the exposure area, between the mask, and the stage for placing thereon a substrate to be exposed, before the exposure light source exposes in operation.

Moving the transparent body horizontally in the preset direction while the exposure light source is exposing in operation, so that there is a change in light journey of greater than 2p²/λ at each exposure position in the exposure area, where p represents the spacing between the periodical patterns in the mask, and λ represents a preset wavelength of the light emitted by the exposure light source.

Generally the transparent body is stopped from moving, after the exposure light source is stopped from exposing.

Optionally in the exposure method above according to the embodiment of the disclosure, the transparent body moves horizontally in the exposure area between the mask, and the stage for placing thereon a substrate to be exposed, instead of the exposed substrate moving upward and downward for exposure in the related art. The transparent body moves horizontally to thereby change longitudinal light journeys at the respective exposure positions in the exposure area, so that the longitudinal light journeys are changed due to the easily manipulated horizontal movement of the transparent body instead of changing the optical distance due to the insignificant movement of the substrate to be exposed, to thereby avoid the poor precision of aligning the moving exposed substrate under a satisfactory exposure condition as needed.

In an optional implementation, in the exposure method above according to the embodiment of the disclosure, moving the transparent body horizontally in the preset direction particularly includes followings.

Moving the transparent body horizontally in the preset direction at a constant velocity so that there is a uniform change in light journey at the respective exposure positions in the exposure area while it is convenient to control the movement velocity of the transparent body to match the length of time for exposure.

Furthermore in an optional implementation, in the exposure method above according to the embodiment of the disclosure, the transparent body can move leftward and rightward repeatedly (i.e. move repeatedly along x axis), or can move unidirectionally, and the movement direction and distance thereof shall be determined according to the length of the exposure time, and the size of the exposure area, although the embodiment of the disclosure will not be limited thereto.

In an optional implementation, in the exposure method above according to the embodiment of the disclosure, when the transparent body is a height-gradually-changing body with a height changing gradually in the horizontal movement direction, there is a uniform refractive index of the height-gradually-changing body; and the height-gradually-changing body is divided into a first height-gradually-changing portion and a second height-gradually-changing portion, both of which are arranged in the horizontal movement direction, that is, the transparent body is structured as illustrated in FIG. 3A and FIG. 3B.

Moving the transparent body horizontally in the preset direction optionally includes followings.

Moving the transparent body so that the first height-gradually-changing portion covers the exposure area at an initial position of the transparent body, and the second height-gradually-changing portion covers the exposure area at a stop position of the transparent body.

Alternatively, moving the transparent body so that the second height-gradually-changing portion covers the exposure area at an initial position of the transparent body, and the first height-gradually-changing portion covers the exposure area at a stop position of the transparent body.

In this way, there can be the same average light journey at the respective exposure positions in the exposure area while there is a uniform change in light journey of greater than 2p²/λ at each exposure position, thus enabling a resulting exposure pattern to be imaged uniformly.

In an optional implementation, in the exposure method above according to the embodiment of the disclosure, the transparent body is a transparent body with a uniform height, and a uniform refractive index changing gradually in the horizontal movement direction; and the transparent body is divided into a first transparent portion and a second transparent portion, both of which are arranged in the horizontal movement direction, that is, the transparent body is structured as illustrated in FIG. 5A and FIG. 5B.

Moving the transparent body horizontally in the preset direction optionally includes followings.

Moving the transparent body so that the first transparent portion covers the exposure area at an initial position of the transparent body, and the second transparent portion covers the exposure area at a stop position of the transparent body.

Alternatively, moving the transparent body so that the second transparent portion covers the exposure area at an initial position of the transparent body, and the first transparent portion covers the exposure area at a stop position of the transparent body.

In this way, there can be the same average light journey at the respective exposure positions in the exposure area while there is a uniform change in light journey of greater than 2p²/λ at each exposure position, thus enabling a resulting exposure pattern to be imaged uniformly.

In the Talbot effect based exposure device, and the exposure method thereof above according to the embodiments of the disclosure, the transparent body moves horizontally in the exposure area between the mask, and the stage for placing thereon a substrate to be exposed, instead of the exposed substrate moving upward and downward for exposure in the related art. Optionally the transparent body is so structured that there is a change in light journey of greater than 2p²/λ at each exposure position in the exposure area while the exposure light source is exposing in operation, where p represents the spacing between the periodical patterns in the mask, and λ, represents a preset wavelength of the light emitted by the exposure light source. The transparent body moves horizontally to thereby change longitudinal light journeys at the respective exposure positions in the exposure area, so that the longitudinal light journeys are changed due to the easily manipulated horizontal movement of the transparent body instead of changing the optical distance due to the insignificant movement of the substrate to be exposed, to thereby avoid the poor precision of aligning the moving exposed substrate under a satisfactory exposure condition as needed.

Evidently those skilled in the art can make various modifications and variations to the disclosure without departing from the spirit and scope of the disclosure. Thus the disclosure is also intended to encompass these modifications and variations thereto so long as the modifications and variations come into the scope of the claims appended to the disclosure and their equivalents.

1. An exposure device, comprising: a stage for placing thereon a substrate to be exposed, a mask arranged above the stage and comprising periodical patterns, an exposure light source arranged above the stage and configured to transmit light at a preset wavelength, and a transparent body configured to move horizontally in a preset direction in an exposure area between the mask and the stage while the exposure light source is exposing in operation, wherein:
the transparent body is so structured that there is a change in light journey, the change in light journey is greater than 2p²/λ at each exposure position in the exposure area while the exposure light source is exposing in operation, wherein p represents a space between the periodical patterns in the mask, and λ represents the preset wavelength.

2. The exposure device according to claim 1, wherein the transparent body is a height-gradually-changing body with a height changing gradually in a horizontal movement direction; and there is a uniform refractive index of the height-gradually-changing body.

3. The exposure device according to claim 2, wherein there is a uniform height of respective cross sections of the height-gradually-changing body in a vertical direction perpendicular to the horizontal movement direction.

4. The exposure device according to claim 2, wherein the height-gradually-changing is divided into a first height-gradually-changing portion and a second height-gradually-changing portion, both of which are arranged in the horizontal movement direction;
a length of the first height-gradually-changing portion is greater than a length a of the exposure area in the horizontal movement direction, and a difference in height of the first height-gradually-changing portion is greater than 2p²/(λ*(n−1)); and
a length of the second height-gradually-changing portion is greater than the length of the exposure area A in the horizontal movement direction, and a difference in height of the second height-gradually-changing portion is greater than 2p²/(λ*(n−1));
wherein n represents a refractive index of the height-gradually-changing body.

5. The exposure device according to claim 4, wherein there is a maximum height at a position where the first height-gradually-changing portion and the second height-gradually-changing portion are connected.

6. The exposure device according to claim 5, wherein there is a symmetry axis at the position where the first height-gradually-changing portion and the second height-gradually-changing portion are connected, and the height-gradually-changing body is structured symmetric with respect to the symmetry axis.

7. The exposure device according to claim 1, wherein the transparent body is a transparent body with a uniform height and a refractive index changing gradually in the horizontal movement direction.

8. The exposure device according to claim 7, wherein there is a uniform refractive index of respective cross sections of the transparent body in a vertical direction perpendicular to the horizontal movement direction.

9. The exposure device according to claim 7, wherein the transparent body is divided into a first transparent portion and a second transparent portion, both of which are arranged in a horizontal movement direction;
a length of the first transparent portion is greater than a length of the exposure area in the horizontal movement direction, and a difference in refractive index of the first transparent portion is greater than 2p²/(λ*H); and
a length of the second transparent portion is greater than the length of the exposure area in the horizontal movement direction, and a difference in refractive index of the second transparent portion is greater than 2p²/(λ*H);
wherein H represents a height of the transparent body

10. The exposure device according to claim 9, wherein there is a maximum refractive index of at a position where the first transparent portion and the second transparent portion are connected.

11. The exposure device according to claim 9, wherein there may be a symmetry axis at the position where the first transparent portion and the second transparent portion are connected, and the transparent body is structured symmetric with respect to the symmetry axis.

12. An exposure method of the exposure device according to claim 1, the method comprises:
arranging the transparent body, covering the exposure area, between the mask and the stage for placing thereon a substrate to be exposed, before the exposure light source exposes in operation; and
moving the transparent body horizontally in the preset direction while the exposure light source is exposing in operation, so that there is a change in light journey of, the change in light journey is greater than 2p²/λ at each exposure position in the exposure area, wherein p represents the space between the periodical patterns in the mask, and λ represents a preset wavelength of light emitted by the exposure light source.

13. The exposure method according to claim 12, wherein moving the transparent body horizontally in the preset direction comprises:
moving the transparent body horizontally in the preset direction at a constant velocity.

14. The exposure method according to claim 13, wherein moving the transparent body horizontally in the preset direction at a constant velocity comprises:
moving the transparent body having a uniform refractive index horizontally at a constant velocity from an initial position of the transparent body to a stop position of the transparent body;
wherein the first height-gradually-changing portion of the transparent body in the horizontal movement direction covers the exposure area at the initial position of the transparent body, and the second height-gradually-changing portion of the transparent body in the horizontal movement direction covers the exposure area at the stop position of the transparent body; or the second height-gradually-changing portion of the transparent body in the horizontal movement direction covers the exposure area at the initial position of the transparent body, and the first height-gradually-changing portion of the transparent body in the horizontal movement direction covers the exposure area at the stop position of the transparent body.

15. The exposure method according to claim 13, wherein moving the transparent body horizontally in the preset direction at a constant velocity comprises:
moving the transparent body having a gradually changing refractive index horizontally at a constant velocity from an initial position of the transparent body to a stop position of the transparent body;
wherein the first transparent portion of the transparent body in the horizontal movement direction covers the exposure area at the initial position of the transparent body, and the second transparent portion of the transparent body in the horizontal movement direction covers the exposure area at the stop position of the transparent body; or the second transparent portion of the transparent body in the horizontal movement direction covers the exposure area at the initial position of the transparent body, and the first transparent portion of the transparent body in the horizontal movement direction covers the exposure area at the stop position of the transparent body.
